(19) United States
(12) Patent Application Publication
(10) Pub. No.: US 2019/0362444 A1
(43) Pub. Date: Nov. 28, 2019

(54) Systems And Methods For Improved Monitoring Of Energy And Water Consumption

(71) Applicant: Christian TERRELL, San Francisco, CA (US)

(72) Inventor: Christian TERRELL, San Francisco, CA (US)

(21) Appl. No.: 15/989,136

(22) Filed: May 24, 2018

(51) Int. Cl. G06Q 50/02; G01R 22/10; G01F 15/06; G06Q 10/06; G06Q 30/02; G06Q 50/06

(52) U.S. Cl. CPC G06Q 50/02; G01R 22/10; G06Q 50/06; G06Q 10/06315; G06Q 30/0283; G01F 15/063

(57) ABSTRACT

Systems and methods for improved monitoring of energy and water consumption where the method includes receiving farm specifications of farms of a user; receiving equipment specifications of equipment of the farms; retrieving data of energy and water consumption for the equipment at a predetermined interval; determining costs of the energy and water consumption in real time; and, transmitting the data and total costs to the user in real time. The equipment may be meters, sub-meters, irrigation pumps, or combinations thereof. The method may further include determining comparative costs of the energy and water consumption in real time of the farms and transmitting the comparative costs to the user. The method may further include determining comparative usage data of energy consumption of the equipment and transmitting the comparative usage data to the user.

### CROSS-REFERENCE TO RELATED APPLICATIONS

Not Applicable

### STATEMENT REGARDING FEDERALLY SPONSORED RESEARCH OR DEVELOPMENT

Not Applicable

### REFERENCE TO SEQUENCE LISTING, A TABLE, OR A COMPUTER PROGRAM LISTING COMPACT DISC APPENDIX

Not Applicable

### BACKGROUND OF THE INVENTION

The present invention is related to software that monitors energy and water consumption, more particularly agricultural energy and water consumption. Farmers may spend up to 50% more on energy than they need to because: (1) lack of data to make informed decisions (cannot manage energy from the field and 90% of energy monitoring is on paper); (2) limited mobile capability and few apps, but 50% of farmers have smartphones; (3) operating with analog equipment and hardware in the field; and, utility bills are complex. In short, farmers cannot manage what they do not measure. The present invention may help reduce farmers' energy spending by up to 50% by providing continuous, full system monitoring to (1) identify patterns/trends and inefficiencies; (2) identify necessary equipment repairs and upgrades; and, (3) notify farmers of better utility rates, rebates & incentives.

The present invention is advantageous because, in part, (1) it keeps ranch owners/farmers informed about energy and water usage by providing actual and historical data and providing predictive recommendations on how utilities are used and can be optimized; (2) it may be utilized by all levels of ranch operations (top level management to ranch hands); and, (3) it automatically draws and interprets data from utility providers; transforms complex bills to display information to user friendly formats.

Embodiments of the invention implement a platform that allows farmers and other agricultural entities to view an accurate, comprehensive, and up-to-the-minute picture of their energy and water consumption. The platform reads energy and water consumption data at specified intervals from any meters desired. This includes more granular information than just an overall farm, building, or like. For instance, the platform can read energy and water consumption data from each different pump on the farm. In this manner, information can be gathered from every point of energy and water consumption.

This provides agricultural entities capabilities that they did not previously have. For example, agricultural entities will be able to view energy and water consumption essentially in real-time, on a per-equipment basis (e.g. per pump, motor, or any other piece of equipment equipped with a water or energy meter), and shut down/adjust individual pieces of equipment as desired to reduce energy/water consumption and thus cost. The platform may track energy/water consumption and transmit alerts when it detects spikes in consumption, on a per-equipment basis. The platform may also track energy/water consumption over time, determine and inform users of their consumption patterns, alert them as to high-consumption periods within the patterns, and alert them when deviations from the patterns occur. Incorporating rate and penalty information also allows the platform to inform users when they are in danger of incurring utility cost penalties due to excessive consumption, and also allows the platform to inform users of more advantageous rates that they may qualify for based on their usage patterns.

### BRIEF SUMMARY OF THE INVENTION

An embodiment of the present invention is a computer system comprising: at least one processor unit; at least one memory unit coupled to the at least one processor unit; and, computer readable instructions embodied in the memory unit and executable by the processor unit, wherein execution of the instructions by the processor unit causes the computing system to perform a method of monitoring of energy and water consumption, the method comprising: receiving farm specifications of one or more farms of a user; receiving equipment specifications of one or more equipment of the one or more farms; wherein the one or more equipment is selected from the group consisting of meters, sub-meters, irrigation pumps, and combinations thereof; retrieving data of energy and water consumption for each of the one or more equipment at a predetermined interval; determining costs of the energy and water consumption in substantial real time; and, transmitting the data and total costs to the user in substantial real time.

Another embodiment of the present invention is a method of monitoring of energy and water consumption, the method comprising: receiving farm specifications of one or more farms of a user; receiving equipment specifications of one or more equipment of the one or more farms; wherein the one or more equipment is selected from the group consisting of meters, sub-meters, irrigation pumps, and combinations thereof; retrieving data of energy and water consumption for each of the one or more equipment at a predetermined interval; determining costs of the energy and water consumption in substantial real time; and, transmitting the data and total costs to the user in substantial real time.

Yet another embodiment of the present invention is a non-transitory computer readable medium having computer readable instructions embodied therein, the computer readable instructions being configured to implement a method of monitoring of energy and water consumption, the method comprising: receiving farm specifications of one or more farms of a user; receiving equipment specifications of one or more equipment of the one or more farms; wherein the one or more equipment is selected from the group consisting of meters, sub-meters, irrigation pumps, and combinations thereof; retrieving data of energy and water consumption for each of the one or more equipment at a predetermined interval; determining costs of the energy and water consumption in substantial real time; and, transmitting the data and total costs to the user in substantial real time.

In another embodiment of the present invention, the user has two or more farms; and, the method further comprises: determining comparative costs of the energy and water consumption in substantial real time of the two or more farms; and, transmitting the comparative costs to the user in substantial real time.

In yet another embodiment of the present invention, the one or more farms has two or more equipment; and, the method further comprises: determining comparative usage data of energy consumption of the two or more equipment in substantial real time; and, transmitting the comparative usage data to the user in substantial real time.

In another embodiment of the present invention, the one or more equipment is an irrigation pump; and, the method further comprises: determining the status of the irrigation pump in substantial real time; transmitting the status to the user in substantial real time; determining the cost intensity of the water consumption in substantial real time; transmitting the cost intensity to the user in substantial real time; determining the pump efficiency in substantial real time; and, transmitting the pump efficiency to the user in substantial real time.

In yet another embodiment of the present invention, the method further comprises: calculating an amount of savings of the one or more farms in substantial real time; wherein the savings comprises costs savings, energy savings, and power demand savings; transmitting the amount to the user in substantial real time; determining recommendations for improving the amount of savings in substantial real time; and, transmitting the recommendations in substantial real time in substantial real time.

In another embodiment of the present invention, the method further comprises: receiving local weather forecast for the one or more farms in substantial real time; receiving one or more irrigation schedules of the one or more farms from the user; calculating an energy cost forecast based upon the local weather forecast and the one or more irrigation schedules in substantial real time; and, transmitting the energy cost forecast to the user in substantial real time.

### BRIEF DESCRIPTION OF THE SEVERAL VIEWS OF THE DRAWING

The advantages and features of the present invention will be better understood as the following description is read in conjunction with the accompanying drawings, wherein:

FIG. 1A-1B are swim-lane diagrams of embodiments of the present invention.

FIG. 2A-2C are swim-lane diagrams of embodiments of the present invention.

FIG. 3 illustrates a computerized system of energy and water consumption monitoring.

FIG. 4 is an example of a computing environment that can be utilized by embodiments of the present invention.

FIG. 5 illustrates an example of a computing system that can be configured to perform any of the processes of the present invention described herein.

FIGS. 6-30 illustrate screenshots of a graphical user interface for implementation of embodiments of the present invention.

For clarity purposes, all reference numerals may not be included in every figure.

### DETAILED DESCRIPTION OF THE INVENTION

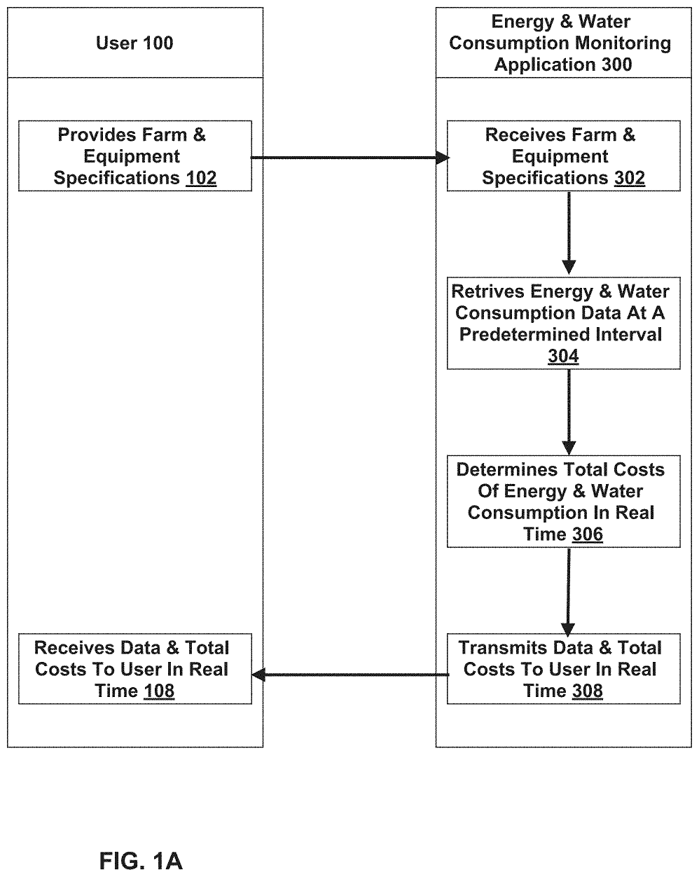

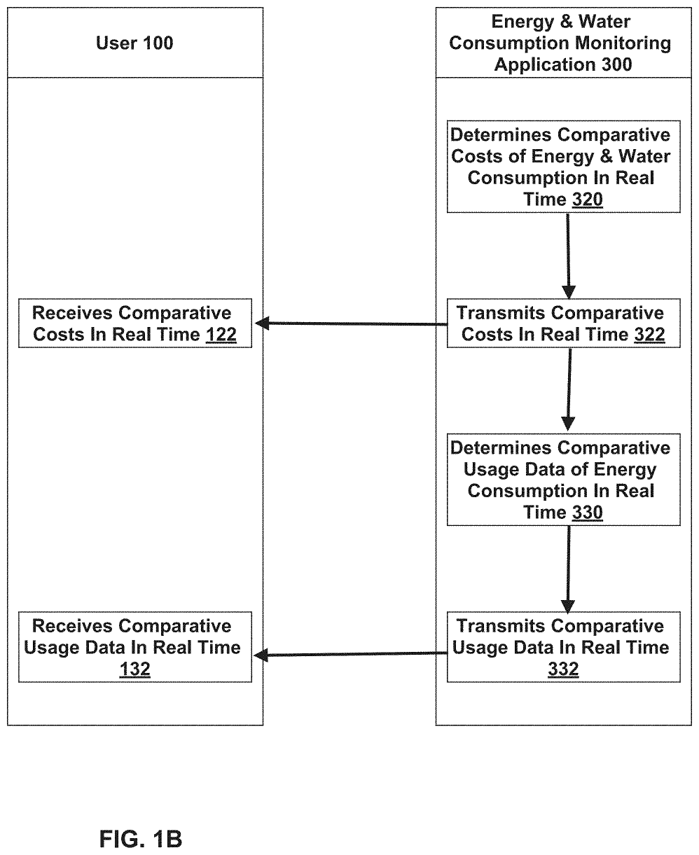

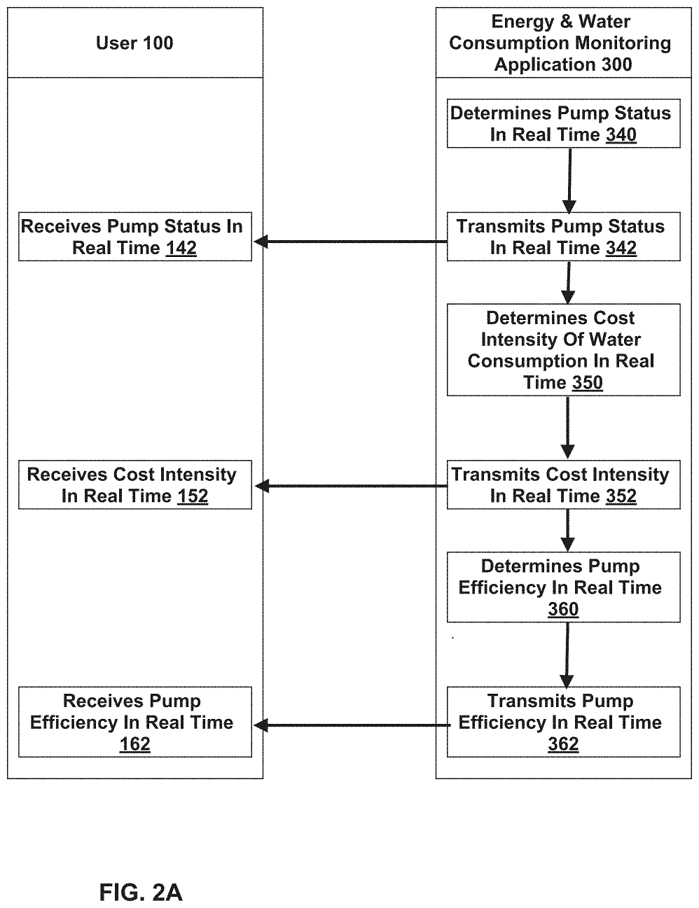

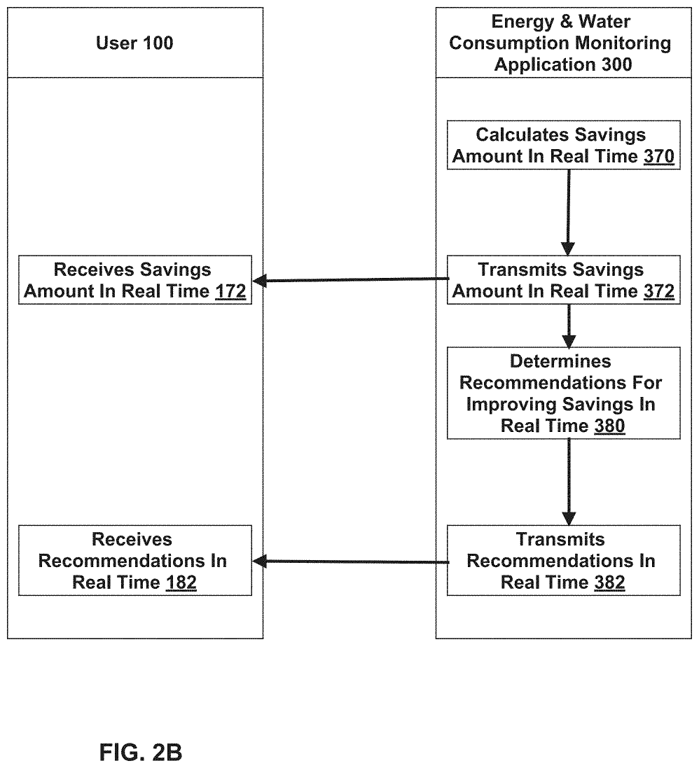

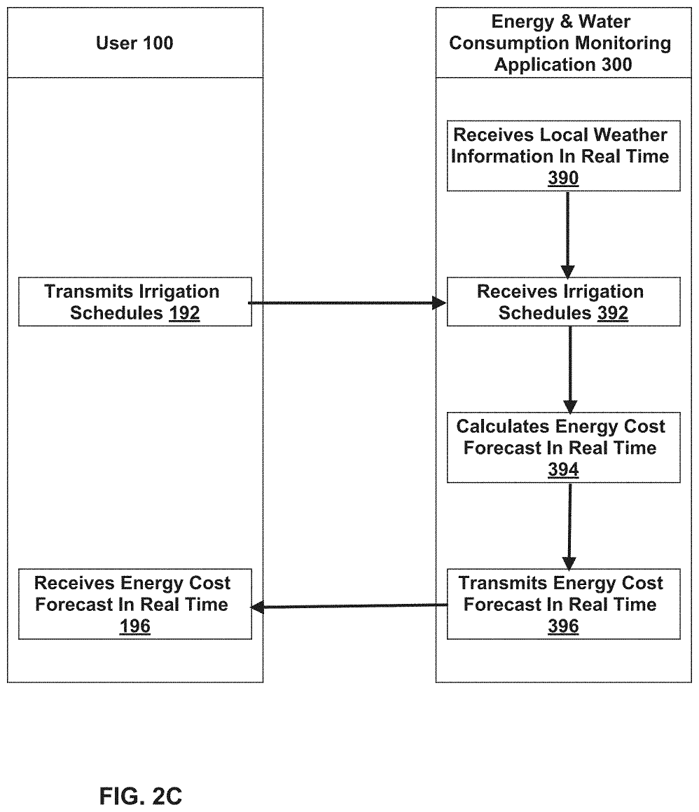

FIGS. 1A-1B and 2A-2C illustrate embodiments of the present invention. FIG. 1A illustrates an embodiment of the present invention where a computer system comprising: at least one processor unit; at least one memory unit coupled to the at least one processor unit; and, computer readable instructions embodied in the memory unit and executable by the processor unit, wherein execution of the instructions by the processor unit causes the computing system to perform a method of monitoring of energy and water consumption.

The method of monitoring of energy and water consumption comprises receiving farm specifications of one or more farms of a user 302 that is provided by a user 102; receiving equipment specifications of one or more equipment of the one or more farms 302 that is provided by a user 102; retrieving data of energy and water consumption for each of the one or more equipment at a predetermined interval 304; determining total costs of the energy and water consumption in substantial real time 306; and, transmitting the data and total costs to the user in substantial real time 308 to the user 108. The one or more equipment may be selected from the group consisting of meters, sub-meters, irrigation pumps, and combinations thereof. The equipment may be located in numerous locations on the farm, such as, corporate offices, cold storage buildings, barns, and any other structure that requires energy. The meters and sub-meters may include, but are not limited to, gas meters, electricity meters, oil meters, and any other meters for measuring utilities. “Predetermined intervals” may be set by the user and may be hourly, daily, monthly, yearly, or any other interval. “Substantial real time” refers to near or at the actual time during which a process or event occurs.

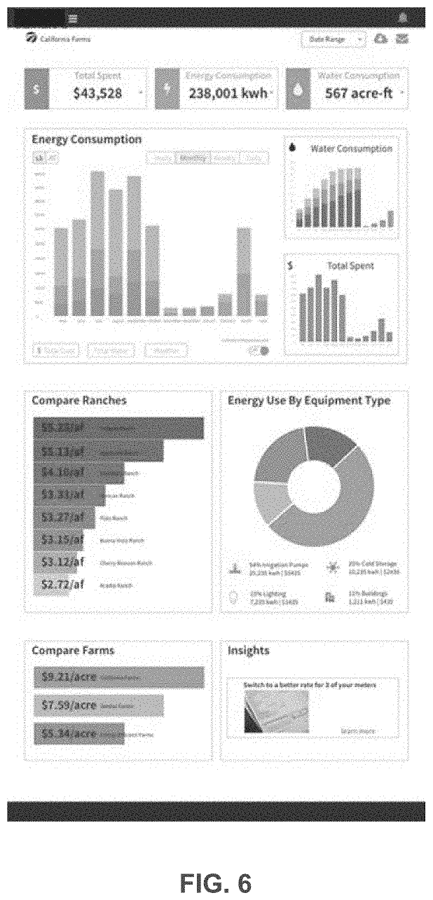

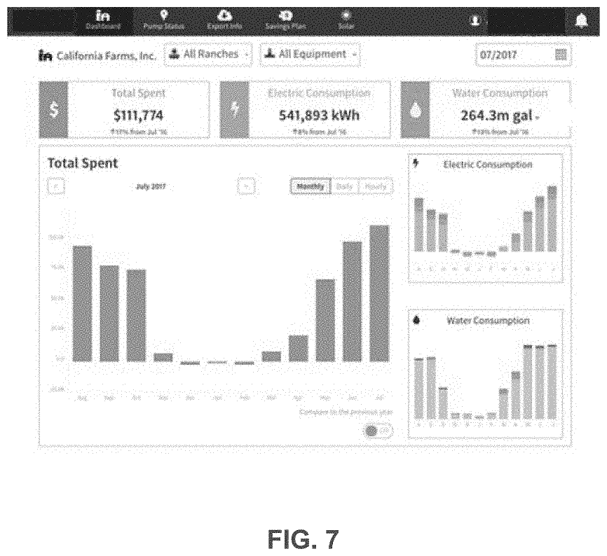

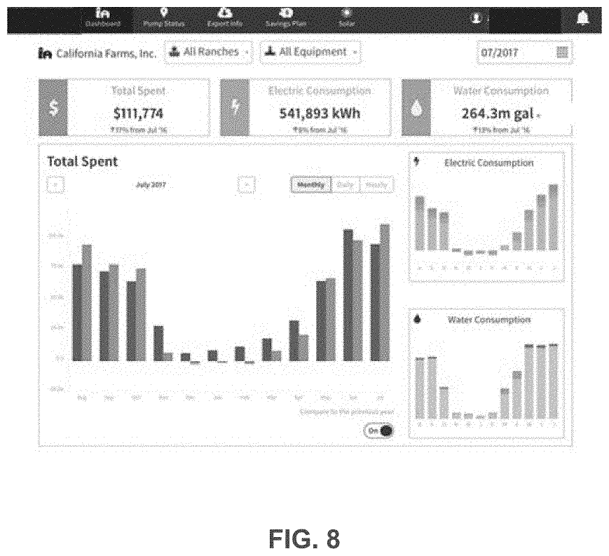

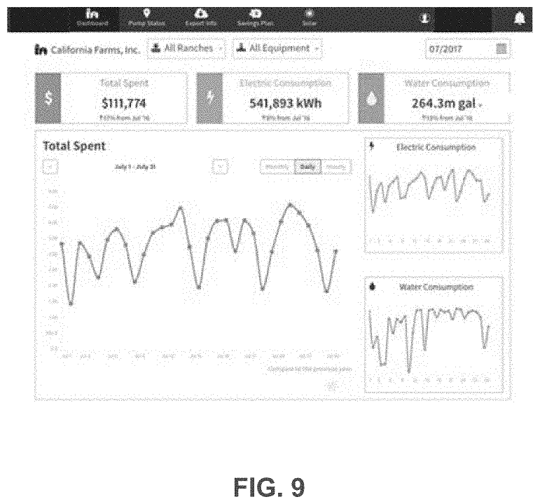

As illustrated in FIG. 1B, in some embodiments of the present invention when the user 100 has two or more farms, the method may further comprise: determining comparative costs of the energy and water consumption in substantial real time of the two or more farms in substantial real time 320, and, transmitting the comparative costs to the user in substantial real time 322. The user 100 then receives the comparative costs in substantial real time 122. FIGS. 6-9 illustrate screenshots of a graphical user interface for implementation of embodiments of the present invention. FIG. 6 illustrates an overall dashboard with graphs for tracking and visualizing energy, water and cost metrics over time. FIG. 7 illustrates a dashboard which displays three charts: energy consumption, water consumption, and energy cost by month. In the energy and water consumption charts, the bars are stacked to show energy or water consumed during peak, partial peak and off peak times of day based on utility time of use (TOU) rate plans. FIG. 8 illustrates an additional button which allows the user to simultaneously toggle between year-over-year time periods to make comparisons in line with changes to farming operations or other factors. As illustrated in FIG. 9, the user within the dashboard may also change the time range of the charts between yearly, monthly, daily and hourly views. The user can then filter the view of their farm's energy from the entire farm as a whole down to a specific piece of equipment such as a building or pump.

Further illustrated in FIG. 1B, in other embodiment of the present invention when the farm has two or more pieces of equipment, the method may further comprise: determining comparative usage data of energy consumption of the equipment 330, and, transmitting the comparative usage data to the user in substantial real time 332. The user 100 then receives the comparative usage data 132.

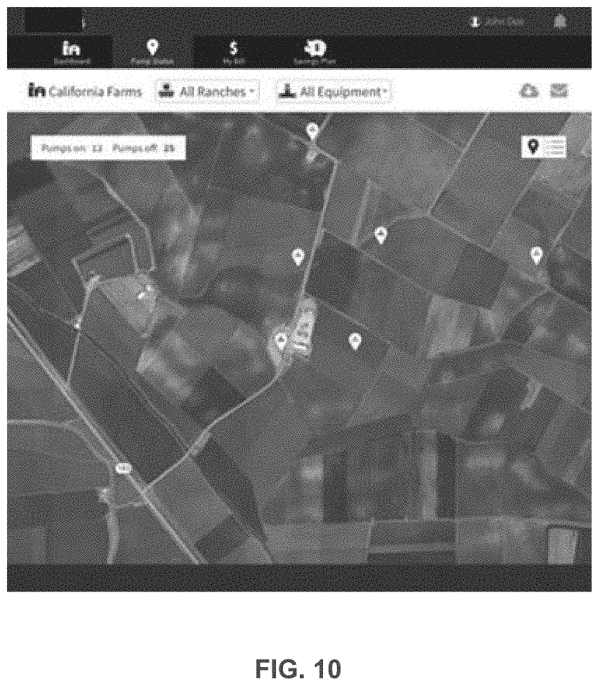

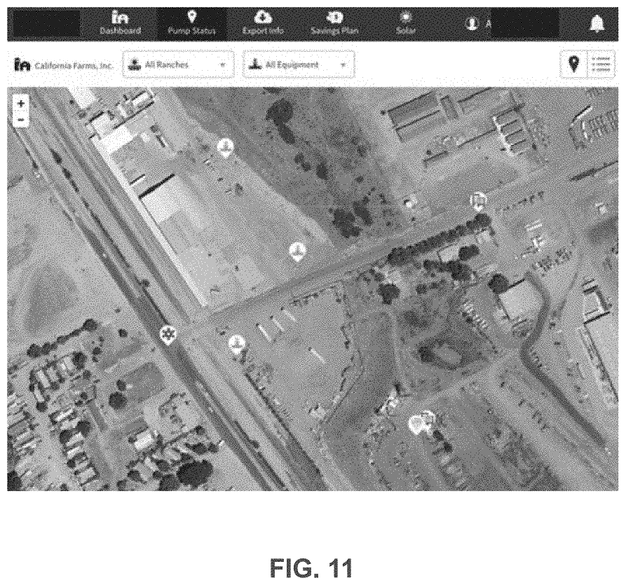

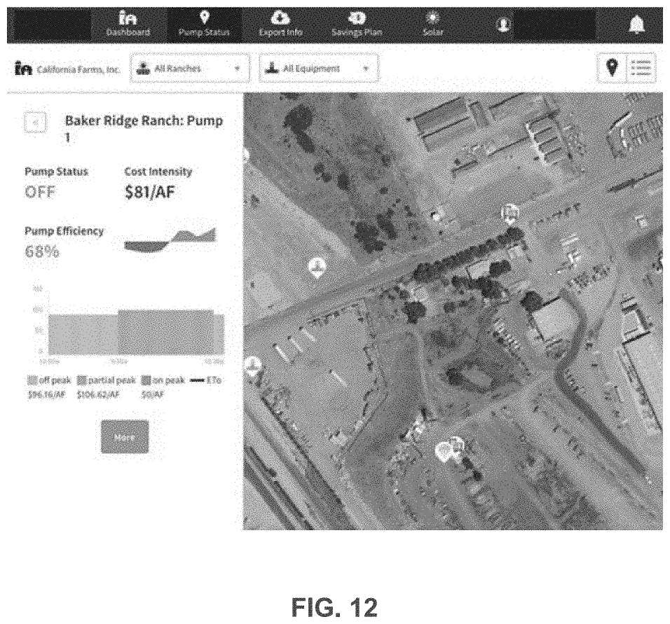

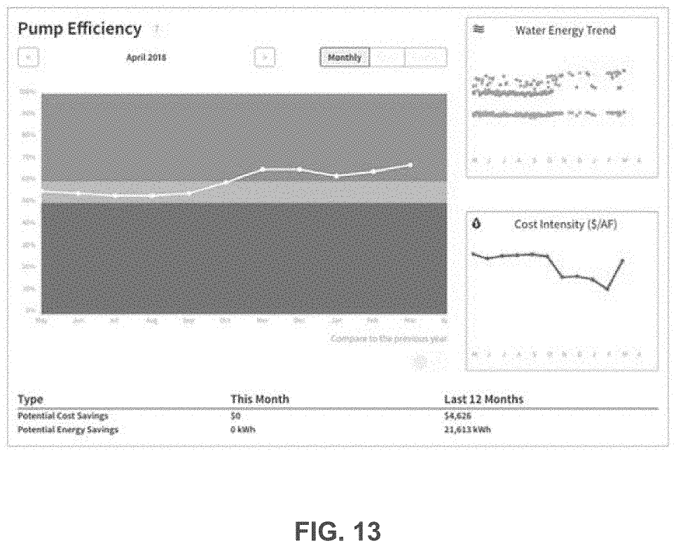

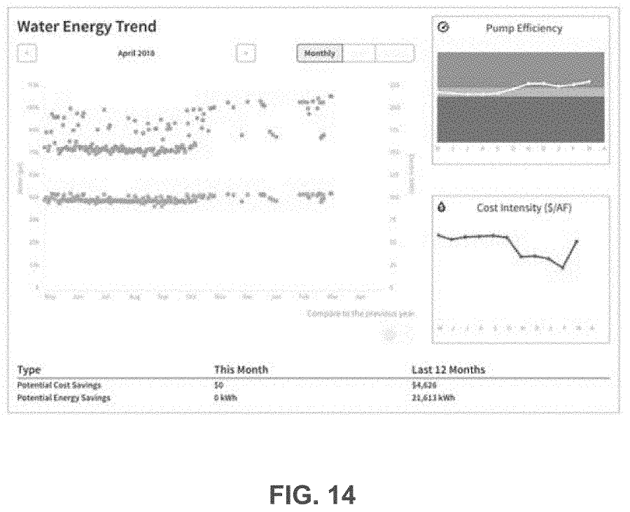

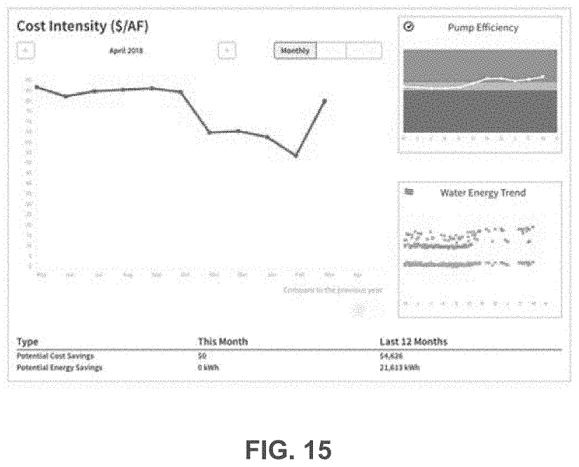

As illustrated in FIG. 2A, in some embodiments when the equipment is an irrigation pump, the method may further comprise: determining the status of the irrigation pump in substantial real time 340, and, transmitting the status to the user in substantial real time 342. The user 100 then receives the status. “Status” refers to whether the irrigation pump is on or off. The method may further comprise: determining the cost intensity of the water consumption in substantial real time 350, and, transmitting the cost intensity to the user in substantial real time 352. The user 100 then receives the cost intensity. The method may further comprise: determining the pump efficiency in substantial real time 360, and, transmitting the pump efficiency to the user in substantial real time 362. The user 100 then receives the pump efficiency 162. FIGS. 10-15 illustrate screenshots of a graphical user interface for implementation of embodiments of the present invention. FIG. 10 illustrates a map which shows the current location and status of all meters, sub-meters, and pumps. FIG. 11 illustrates a map of a user's farm with icons placed over the location of the various irrigation pumps, buildings, cold storage units and other farm features. FIG. 12 illustrates that when an icon is clicked on, a small panel displays more detailed information about what is happening with that piece of equipment at that moment, such as pump status, cost intensity, and pump efficiency. FIG. 13 illustrates three charts: pump efficiency, water energy trend, and cost intensity. The first chart tracks the pump's efficiency by month. Efficiency is calculated using an industry standard equation with several variables: total dynamic lift, water flow rate, discharge pressure, and energy usage. In addition to tracking the efficiency value, the chart also shows the user if the efficiency level is high enough within industry standards. When the number appears in the top portion, it indicates good efficiency. When the number lands in middle portion, it indicates that the pump's efficiency is dropping and the pump may need some maintenance to get back up to a healthy level. A number appearing in the bottom portion indicates that pump efficiency is very low and the pump may fail soon. FIG. 14 illustrates the second chart, which shows the trend of water use at any given interval against energy use for the same interval. When a pump is healthy, top set of points (water) and lower set of points (energy) should fall across the chart in a relatively flat line. However, if one of the fields of points decreases while the other remains flat, it can indicate problems such as a decrease in efficiency, cracked well bowl etc. FIG. 15 illustrates the third chart, which shows cost intensity. This chart measures the cost per acre-foot of water pumped. This chart illustrates the cost/benefit of maintaining good pump efficiency as when pump efficiency goes up the cost per acre-foot of water goes down.

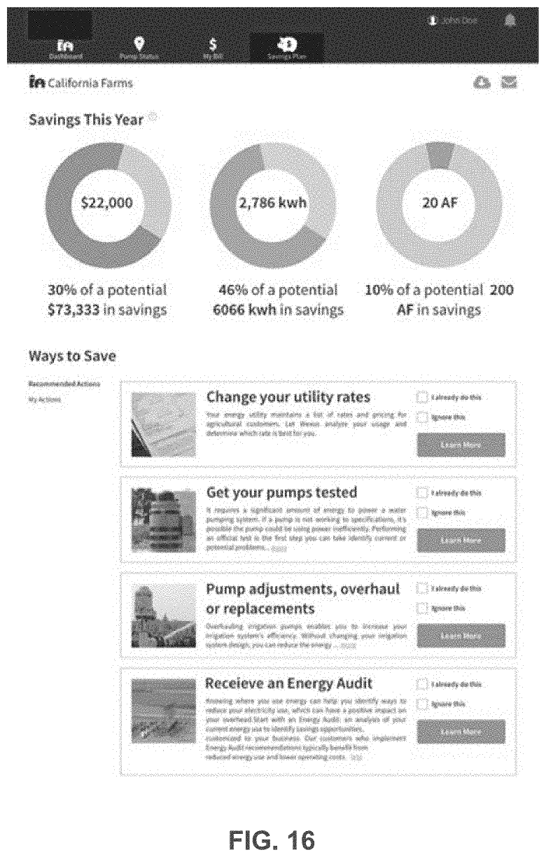

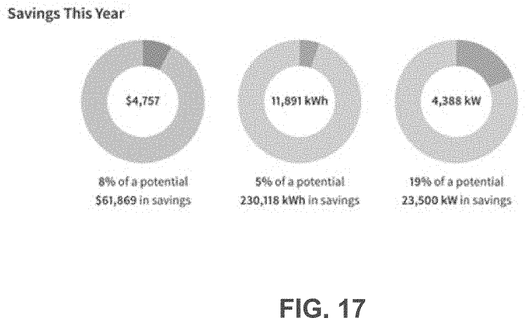

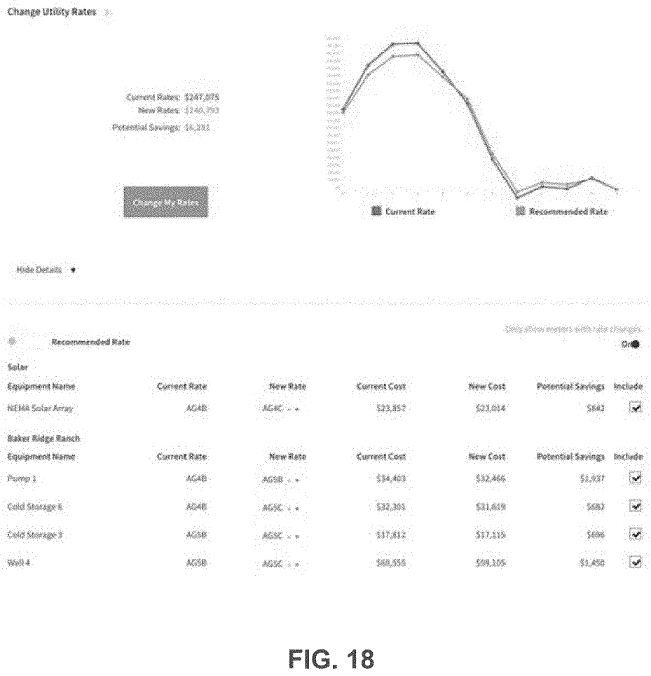

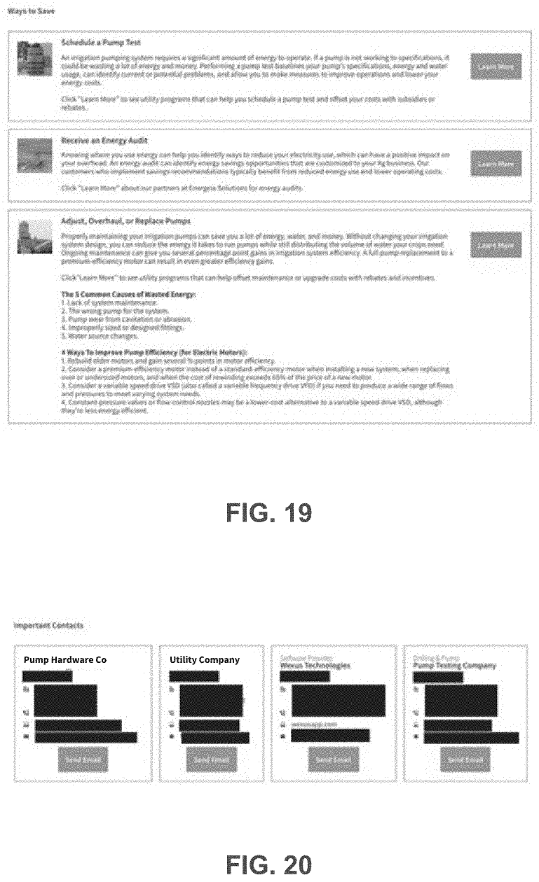

As illustrated in FIG. 2B, in some embodiments, the method may further comprise: calculating an amount of savings of the one or more farms in substantial real time 370, and, transmitting the amount to the user in substantial real time 372. The user 100 then receives the amount 172. The method may further comprise: determining recommendations for improving the amount of savings in substantial real time 380, and, transmitting the recommendations in substantial real time 382. The user 100 then receives the recommendations 182. The savings may comprise costs savings, energy (kilowatt-hour kWh) savings, and power (kilowatt kW) demand savings. FIGS. 16-20 illustrate screenshots of a graphical user interface for implementation of embodiments of the present invention. FIG. 16 illustrates a “Savings Plan” page to track a user farm's cost, energy (kWh) and power (kW) demand savings, and tips with links to utility programs to help them save further. FIG. 17 illustrates several pie charts which track the total potential savings and actual savings in dollars, kilowatts, and kilowatt-hours across the company. FIG. 18 illustrates energy costs the user under their current rates and what energy would cost under the new rates. The user can also examine other scenarios besides the energy and water consumption monitoring application 300 recommended rates to see how their costs could change. Once they have chosen their new rate plans, the user can click the button in this section to send a notification to the energy and water consumption monitoring application 300 to contact the utility company and have the rates changed on the user's behalf. The energy and water consumption monitoring application 300 help the user choose energy rates for their meters and then get their rates changed by their utility company. Using the last 12 months of energy data for each meter and the latest agricultural rate plans from their utility company, the energy and water consumption monitoring application 300 calculates various scenarios and recommends new rates for each meter. FIG. 19 illustrates recommendations on further ways to save. The recommendations are customized to the user's utility company and provide links to places where they can get more information or take action. FIG. 20 illustrates important contacts which are all energy and water related and provides a place for the users to quickly find the vendors they need for all their energy and water related needs. The energy and water consumption monitoring application 300 may identify trends and inefficiencies related to the energy and water consumption. The recommendations may be based upon these trends and inefficiencies.

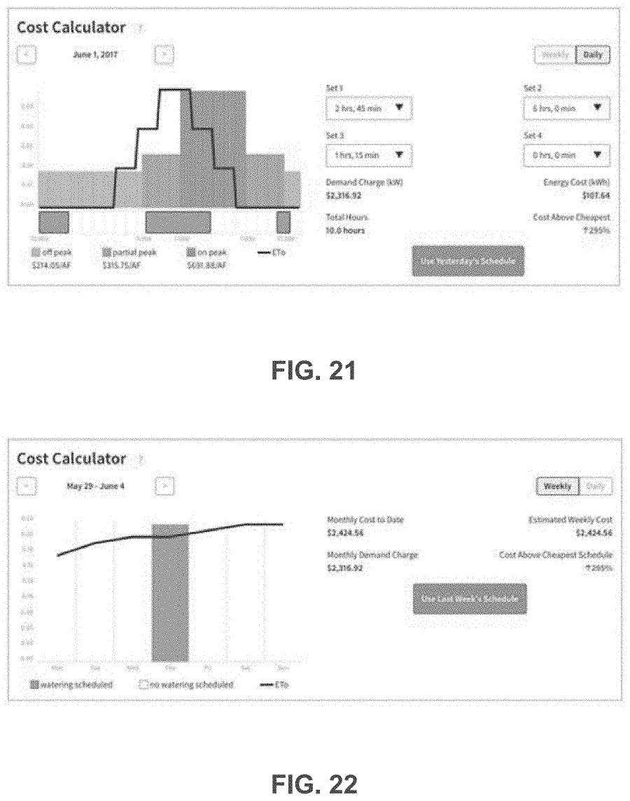

As illustrated in FIG. 2C, in some embodiments, the method may further comprise: receiving local weather forecast for the farms in substantial real time 390; receiving irrigation schedules of the farms 392 transmitted from the user 192; calculating an energy cost forecast based upon the local weather forecast and the irrigation schedules in substantial real time 394; and, transmitting the energy cost forecast to the user in substantial real time 396. The user 100 then receives the energy cost forecast 196. FIGS. 21-22 illustrate screenshots of a graphical user interface for implementation of embodiments of the present invention. FIG. 21 illustrates a “Cost Calculator” which allows users to forecast the energy costs related to a given irrigation schedule in advance of using any water. The Cost Calculator helps users make more informed decisions about their watering habits. A chart shows the cost per acre-foot of water during off-peak, partial peak, and peak times of day and overlays this information with their local weather information. In one embodiment, the user can enter up to four irrigation sets in a day and shift what time those irrigation sets occur. As the user changes the irrigation set information, the cost associated with that schedule is updated. FIG. 22 illustrates both a daily view and a weekly view of their irrigation schedule and associated costs.

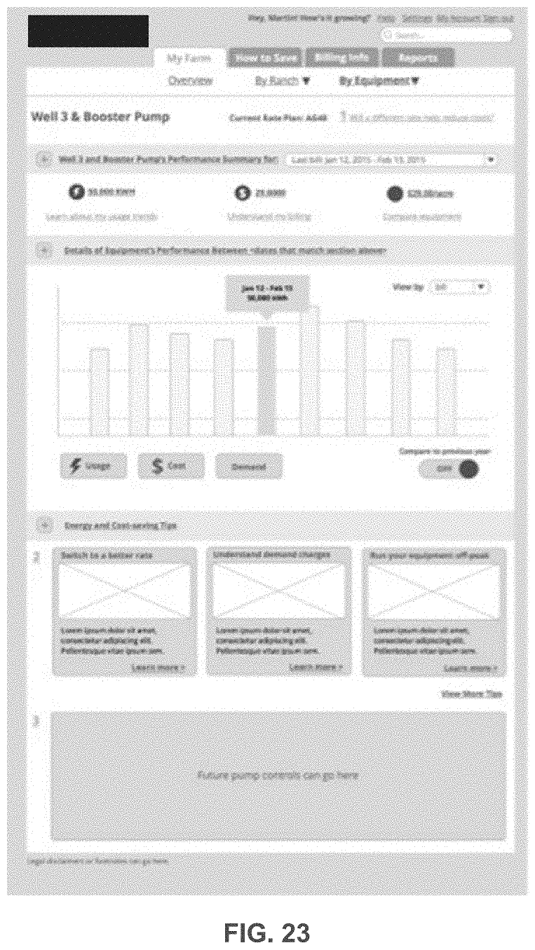

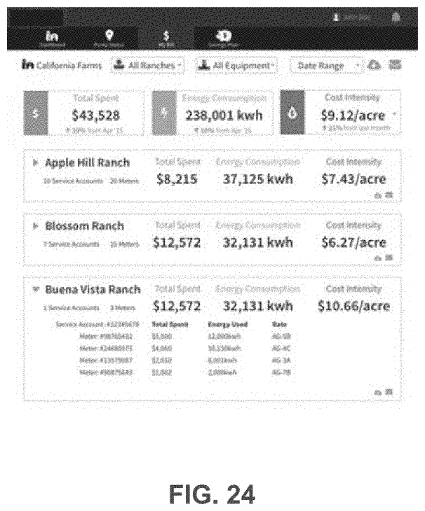

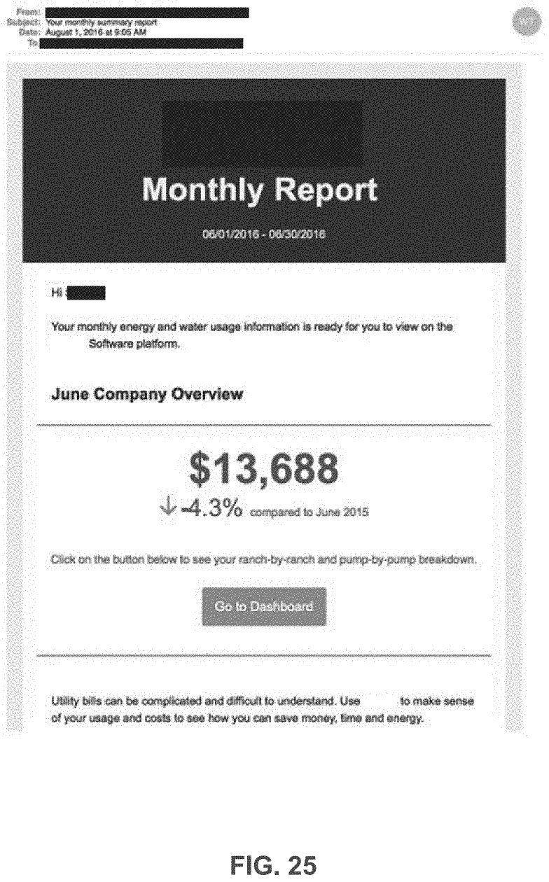

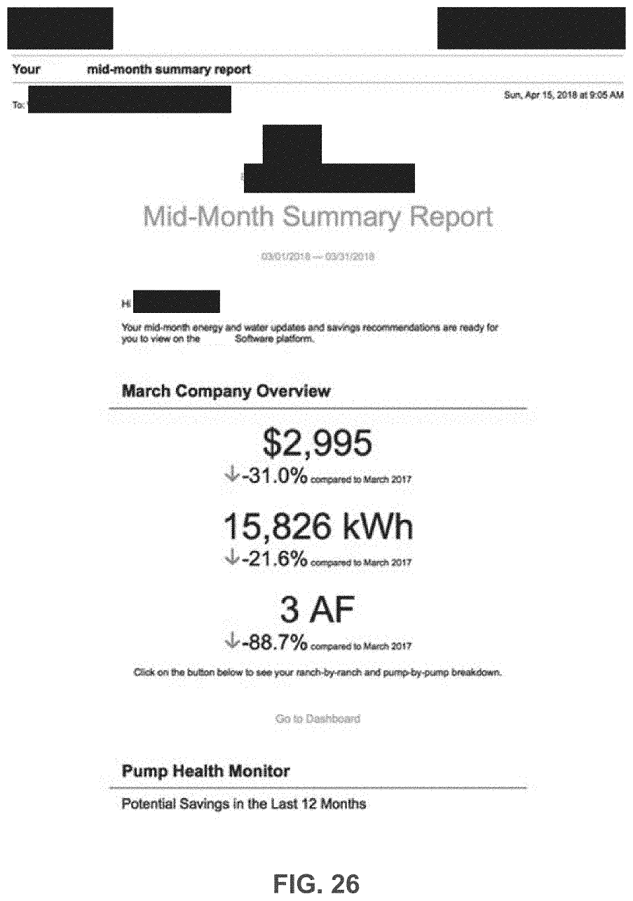

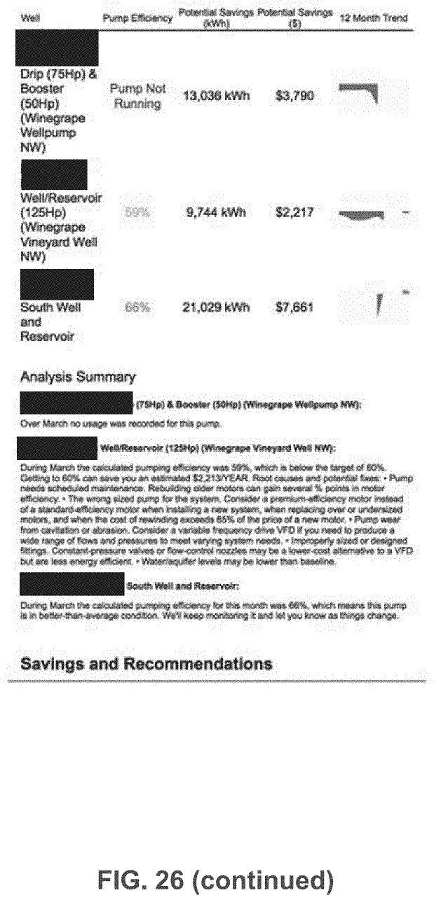

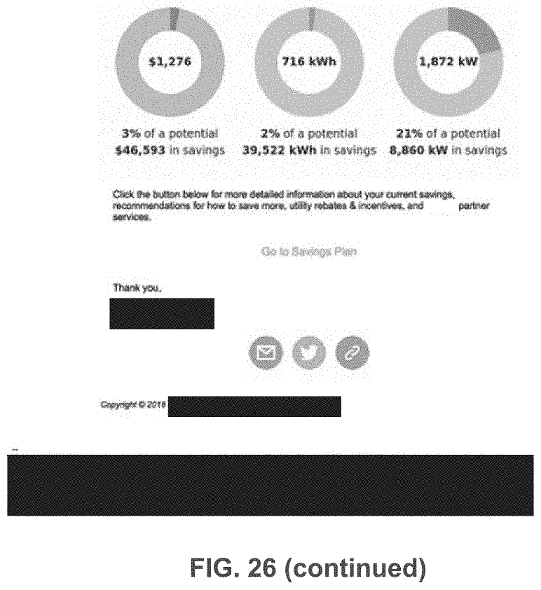

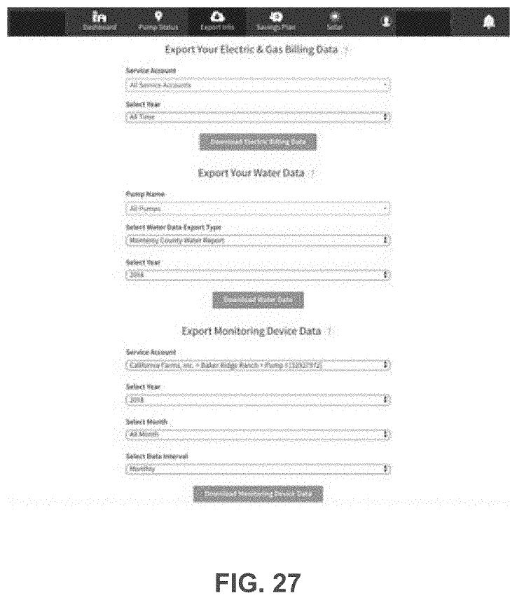

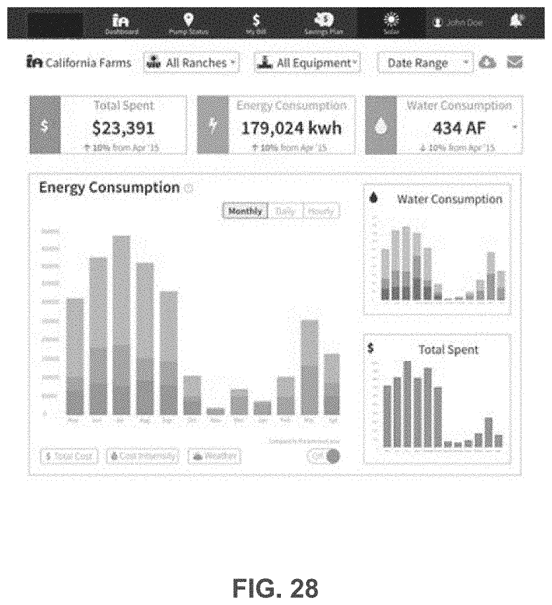

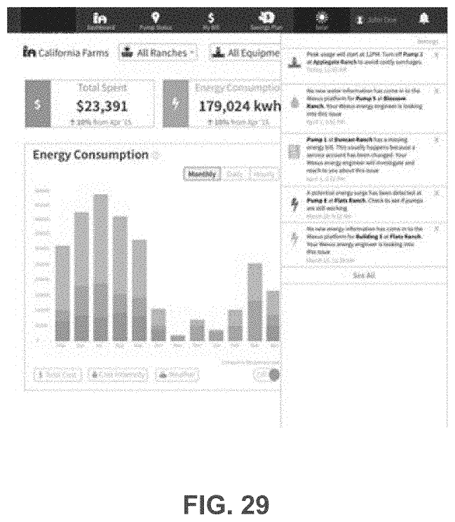

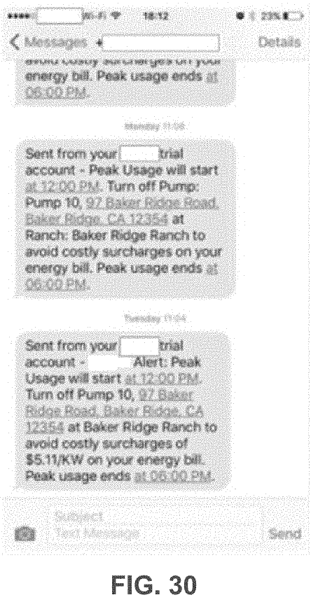

FIGS. 23-30 illustrate screenshots of a graphical user interface for implementation of embodiments of the present invention. FIG. 23 illustrates a representative dashboard. FIG. 24 illustrates a representative download page, where energy and water consumption data may be downloaded in CSV format. FIG. 25 illustrates a representative monthly email report, which provides a monthly summary of the user's energy use. FIG. 26 illustrates a bi-weekly site energy report email. FIG. 27 illustrates a representative data export page, where the user can select to export electric or gas related billing data, water data as well as other monitoring device data for their farm by billing period, year, month or day. FIGS. 28-30 illustrated various alerts. FIG. 28 illustrates if an alert was sent, when users log into the energy and water consumption monitoring application 300, they see a number indicating the number of unread alerts which appear in the top right corner over a bell icon. FIG. 29 illustrates when they click the icon, the alerts appear and can be clicked on to go to the page in the energy and water consumption monitoring application 300 where the most relevant information regarding the alert is displayed. Each alert is paired with an icon to quickly inform the user to the type of alert and the level of urgency associated with the alert. FIG. 30 illustrates a representative SMS alert. When analysis uncovers an issue that needs to be addressed by the user immediately, such as a high peak energy usage or dropping pump efficiency, an alert is automatically sent to the user via text message to their cell phone. This style of alert allows them to see the alert even when not in front of their computer and act quickly to address the issue which is critical for farming operations in the field.

Another embodiment of the present invention is a non-transitory computer readable medium having computer readable instructions embodied therein, the computer readable instructions being configured to implement a method of monitoring of energy and water consumption when executed. “Non-transitory computer readable medium” may not include a transitory signal.

The method of monitoring of energy and water consumption comprises receiving farm specifications of one or more farms of a user 302 that is provided by a user 102; receiving equipment specifications of one or more equipment of the one or more farms 302 that is provided by a user 102; retrieving data of energy and water consumption for each of the one or more equipment at a predetermined interval 304; determining total costs of the energy and water consumption in substantial real time 306; and, transmitting the data and total costs to the user in substantial real time 308 to the user 108.

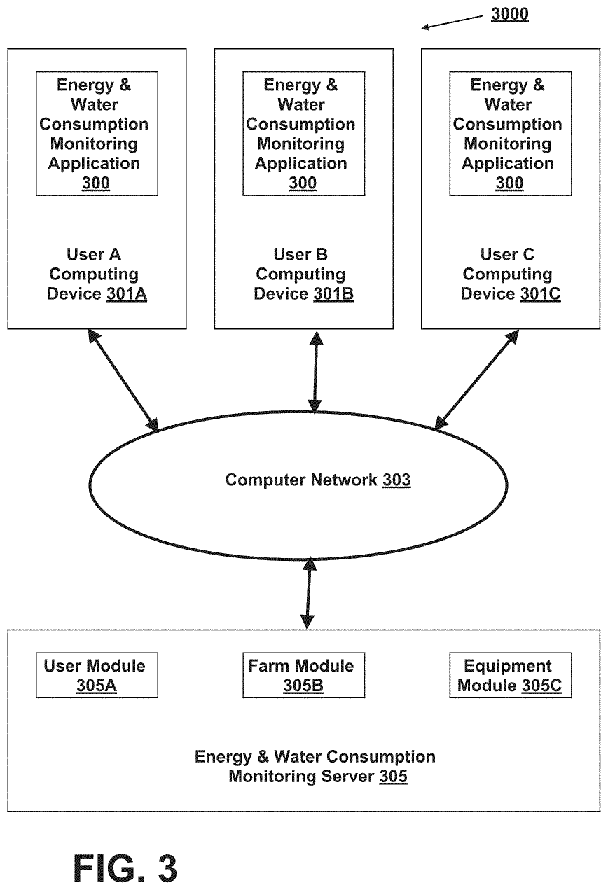

The enabled computing devices 301A, 301B, 301C of FIG. 3 may include such devices as tablet computers, smartphones, personal computers, laptop computers, scanners, game consoles and the like. The energy and water consumption monitoring application 300 may be software designed to help the users 100 monitor the energy and water consumption of a farm. The energy and water consumption monitoring application 300 may also communicate with the energy and water consumption monitoring server 305 through the computer network 303. The computer network 303 may be, for example, the internet.

The energy and water consumption monitoring server 305 may contain various modules, including the user module 305A, the farm module 305B, and the equipment module 305C. Each module 305A, 305B, 305C may store data. For example, the user module 305A may store the user's 100 background (e.g., name, location, account number, login name, passwords, title), and other information. The farm module 305B may store information, details, and descriptions of the farm (e.g., name, location, acreage), and other information. The equipment module 305C may store the information, details, and descriptions of the equipment (e.g., name, location, type, age, manufacturer, warranty information, serial number, model number), and other information. The energy and water consumption monitoring server 305 may contain various other modules not shown, such as, a module that may store costs information.

“User” may refer to any agricultural personnel, including, but not limited to, ranch managers, sustainability managers, general managers, and ranch administrators. A Ranch Manager may oversees a crew of laborers on a ranch/farm and is responsible for the crop yield, fertilizer application, irrigation schedule, and equipment maintenance. The Ranch Manager is usually is strapped for time, has to meet tight deadlines, is under pressure to maximize yields while lowering costs, needs better access to energy data (usage and cost), and is managing vendors and employees all day long. A Sustainability Manager of an agricultural company needs quick and easy access to data and has to meet corporate sustainability goals. The Sustainability Manager also spends a lot of time manually gathering data and has to constantly achieve buy-in from managers across the company to implement sustainability measures. A General Manager of an agricultural company has P&L responsibility for multiple ranches/farms and a large number of employees. The General Manager is usually under pressure to meet production targets and lower costs, has to meet tight deadlines, needs to meet regulatory requirements for reporting energy and water usage, and also needs better tools to manage and report resource usage (energy, water, fertilizer runoff), but local utilities (electrical company, water agency) are not helpful. A Ranch Administrator of an agricultural company is responsible for accounting, reporting and processing data and bills, data entry, communicating with vendors, and reporting to the CFO and GM. The Ranch Administrator also has deadlines to meet and must enter and report data (usage and cost data entered into spreadsheets).

“Farm” may refer to any agricultural entity, such as arable farms, pastoral farms, mixed farms, ranches, and other agricultural entities.

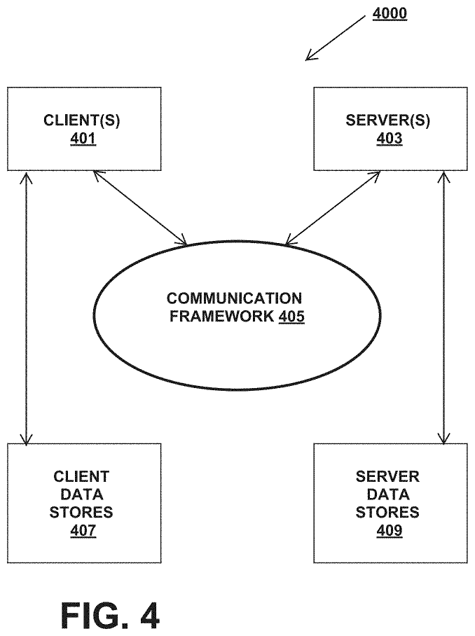

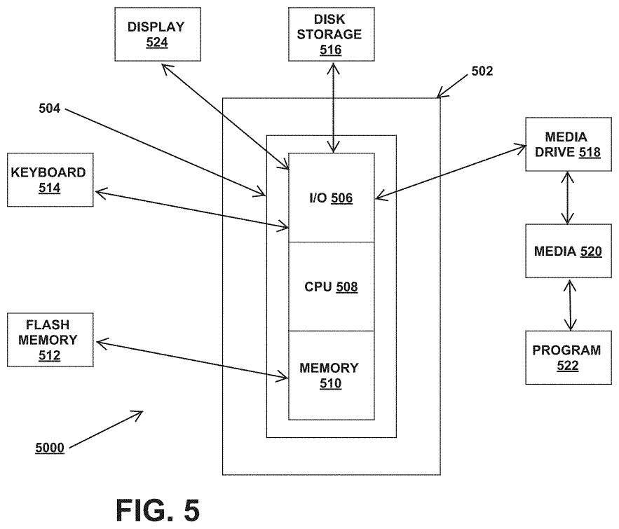

FIGS. 4 and 5 illustrate exemplary computing environments, devices and architectures for the implementation of the various embodiments of the present invention.

FIG. 4 illustrates a sample computing environment 4000 that can be utilized in some embodiments. The system 4000 further illustrates a system that includes one or more client(s) 401. The client(s) 401 can be hardware and/or software (e.g., threads, processes, computing devices). The system 4000 also includes one or more server(s) 403, such as energy and water consumption monitoring server 305. The server(s) 403 can also be hardware and/or software (e.g., threads, processes, computing devices). One possible communication between a client 401 and a server 403 may be in the form of a data packet adapted to be transmitted between two or more computer processes. The system 4000 includes a communication framework 405 that can be utilized to facilitate communications between the client(s) 401 and the server(s) 403. The client(s) 401 are connected to one or more client data store(s) 407 that can be employed to store information local to the client(s) 401. Similarly, the server(s) 403 are connected to one or more server data store(s) 409 that can be employed to store information local to the server(s) 403.

FIG. 5 depicts an exemplary computing system 5000 that can be configured to perform any one of the above-described processes. In this context, computing system 5000 may include, for example, a processor, memory, storage, and I/O devices (e.g., monitor, keyboard, disk drive, Internet connection, etc.). However, computing system 5000 may include circuitry or other specialized hardware for carrying out some or all aspects of the processes. In some operational settings, computing system 5000 may be configured as a system that includes one or more units, each of which is configured to carry out some aspects of the processes either in software, hardware, or some combination thereof.

FIG. 5 depicts computing system 5000 with a number of components that may be used to perform the above-described processes. The main system 502 includes a motherboard 504 having an I/O section 506, one or more central processing units (CPU) 508, and a memory section 510, which may have a flash memory card 512 related to it. The I/O section 506 is connected to a display 524, a keyboard 514, a disk storage unit 516, and a media drive unit 518. The media drive unit 518 can read/write a computer-readable medium 520, which can contain programs 522 and/or data. Although, not shown, in some embodiments, computing system 500 can include an eye-tracking system and/or be coupled with an eye-tracking system.

While the invention has been described with reference to exemplary embodiments, it will be understood by those skilled in the art that various changes, omissions, and/or additions may be made and equivalents may be substituted for elements thereof without departing from the spirit and scope of the invention. In addition, many modifications may be made to adapt a particular situation or material to the teachings of the invention without departing from the scope thereof. Therefore, it is intended that the invention not be limited to the particular embodiments disclosed as the best mode contemplated for carrying out this invention, but that the invention will include all embodiments falling within the scope of the appended claims. Moreover, unless specifically stated any use of the terms first, second, etc. do not denote any order or importance, but rather the terms first, second, etc. are used to distinguish one element from another.

I claim:

1. A computer system comprising:
at least one processor unit;
at least one memory unit coupled to the at least one processor unit; and,
computer readable instructions embodied in the memory unit and executable by the processor unit, wherein execution of the instructions by the processor unit causes the computing system to perform a method of monitoring of energy and water consumption, the method comprising:
receiving farm specifications of one or more farms of a user;
receiving equipment specifications of one or more equipment of the one or more farms; wherein the one or more equipment is selected from the group consisting of meters, sub-meters, irrigation pumps, and combinations thereof;
retrieving data of energy and water consumption for each of the one or more equipment at a predetermined interval;
determining total costs of the energy and water consumption in substantial real time; and,
transmitting the data and total costs to the user in substantial real time.

2. The computer system of claim 1, wherein the user has two or more farms; and,
wherein the method further comprises:
determining comparative costs of the energy and water consumption in substantial real time of the two or more farms in substantial real time; and,
transmitting the comparative costs to the user in substantial real time.

3. The computer system of claim 1, wherein the one or more farms has two or more equipment; and,
wherein the method further comprises:
determining comparative usage data of energy consumption of the two or more equipment; and,
transmitting the comparative usage data to the user in substantial real time.

4. The computer system of claim 1, wherein the one or more equipment is an irrigation pump; and,
wherein the method further comprises:
determining the status of the irrigation pump in substantial real time;
transmitting the status to the user in substantial real time;
determining the cost intensity of the water consumption in substantial real time;
transmitting the cost intensity to the user in substantial real time;
determining the pump efficiency in substantial real time; and,
transmitting the pump efficiency to the user in substantial real time.

5. The computer system of claim 1, wherein the method further comprises:
calculating an amount of savings of the one or more farms in substantial real time; wherein the savings comprises costs savings, energy savings, and power demand savings;
transmitting the amount to the user in substantial real time;
determining recommendations for improving the amount of savings in substantial real time; and,
transmitting the recommendations in substantial real time.

6. The computer system of claim 1, wherein the method further comprises:
receiving local weather forecast for the one or more farms in substantial real time;
receiving one or more irrigation schedules of the one or more farms from the user;
calculating an energy cost forecast based upon the local weather forecast and the one or more irrigation schedules in substantial real time; and,
transmitting the energy cost forecast to the user in substantial real time.

7. A method of monitoring of energy and water consumption, the method comprising:
receiving farm specifications of one or more farms of a user;
receiving equipment specifications of one or more equipment of the one or more farms; wherein the one or more equipment is selected from the group consisting of meters, sub-meters, irrigation pumps, and combinations thereof;
retrieving data of energy and water consumption for each of the one or more equipment at a predetermined interval;
determining total costs of the energy and water consumption in substantial real time; and,
transmitting the data and total costs to the user in substantial real time.

8. The method of claim 7, wherein the user has two or more farms; and,
wherein the method further comprises:
determining comparative costs of the energy and water consumption in substantial real time of the two or more farms; and,
transmitting the comparative costs to the user in substantial real time.

9. The method of claim 7, wherein the one or more farms has two or more equipment; and,
wherein the method further comprises:
determining comparative usage data of energy consumption of the two or more equipment in substantial real time; and,
transmitting the comparative usage data to the user in substantial real time.

10. The method of claim 7, wherein the one or more equipment is an irrigation pump; and,
wherein the method further comprises:
determining the status of the irrigation pump in substantial real time;
transmitting the status to the user in substantial real time;
determining the cost intensity of the water consumption in substantial real time;
transmitting the cost intensity to the user in substantial real time;
determining the pump efficiency in substantial real time; and,
transmitting the pump efficiency to the user in substantial real time.

11. The method of claim 7 further comprises:
calculating an amount of savings of the one or more farms in substantial real time; wherein the savings comprises costs savings, energy savings, and power demand savings;
transmitting the amount to the user in substantial real time;
determining recommendations for improving the amount of savings in substantial real time; and,
transmitting the recommendations in substantial real time.

12. The method of claim 7 further comprises:
receiving local weather forecast for the one or more farms in substantial real time;
receiving one or more irrigation schedules of the one or more farms from the user;
calculating an energy cost forecast based upon the local weather forecast and the one or more irrigation schedules in substantial real time; and,
transmitting the energy cost forecast to the user in substantial real time.

13. A non-transitory computer readable medium having computer readable instructions embodied therein, the computer readable instructions being configured to implement a method of monitoring of energy and water consumption when executed, the method comprising:
receiving farm specifications of one or more farms of a user;
receiving equipment specifications of one or more equipment of the one or more farms; wherein the one or more equipment is selected from the group consisting of meters, sub-meters, irrigation pumps, and combinations thereof;
retrieving data of energy and water consumption for each of the one or more equipment at a predetermined interval;
determining total costs of the energy and water consumption in substantial real time; and,
transmitting the data and total costs to the user in substantial real time.

14. The non-transitory computer readable medium of claim 13, wherein the user has two or more farms; and,
wherein the method further comprises:
determining comparative costs of the energy and water consumption in substantial real time of the two or more farms; and,
transmitting the comparative costs to the user in substantial real time.

15. The non-transitory computer readable medium of claim 13, wherein the one or more farms has two or more equipment; and,
wherein the method further comprises:
determining comparative usage data of energy consumption of the two or more equipment in substantial real time; and,
transmitting the comparative usage data to the user in substantial real time.

16. The non-transitory computer readable medium of claim 13, wherein the one or more equipment is an irrigation pump; and,
wherein the method further comprises:
determining the status of the irrigation pump;
transmitting the status to the user in substantial real time;
determining the cost intensity of the water consumption;
transmitting the cost intensity to the user in substantial real time;
determining the pump efficiency; and,
transmitting the pump efficiency to the user in substantial real time.

17. The non-transitory computer readable medium of claim 13, wherein the method further comprises:
calculating an amount of savings of the one or more farms; wherein the savings comprises costs savings, energy savings, and power demand savings;
transmitting the amount to the user in substantial real time;
determining recommendations for improving the amount of savings; and,
transmitting the recommendations in substantial real time.

18. The non-transitory computer readable medium of claim 13, wherein the method further comprises:
receiving local weather forecast for the one or more farms in substantial real time;
receiving one or more irrigation schedules of the one or more farms from the user;
calculating an energy cost forecast based upon the local weather forecast and the one or more irrigation schedules in substantial real time; and,
transmitting the energy cost forecast to the user in substantial real time.
